(19) United States
(12) Patent Application Publication
(10) Pub. No.: US 2023/0040128 A1
(43) Pub. Date: Feb. 9, 2023

(54) ELECTRICAL CONNECTING STRUCTURE AND METHOD FOR MANUFACTURING THE SAME

(71) Applicant: NATIONAL YANG MING CHIAO TUNG UNIVERSITY, Hsinchu City (TW)

(72) Inventors: Chih CHEN, Hsinchu City (TW); Jia-Juen ONG, Hsinchu City (TW); Kuan-Ju CHEN, Kaohsiung City (TW); Chang-Chih HSIEH, Taoyuan City (TW)

(21) Appl. No.: 17/570,241

(22) Filed: Jan. 6, 2022

(30) Foreign Application Priority Data
Aug. 9, 2021 (TW) 110129246

(51) Int. Cl. H01L 23/00; H05K 1/14; H05K 1/18; H05K 3/30

(52) U.S. Cl. CPC H01L 24/16; H01L 24/81; H01L 24/13; H05K 1/144; H05K 1/181; H05K 3/301; H01L 2224/16145; H01L 2224/16225; H01L 2224/13147; H01L 2224/13005

(57) ABSTRACT

An electrical connecting structure and a method for manufacturing the same are disclosed. The electrical connecting structure comprises: a first substrate; a second substrate; and an interconnect element disposed between the first substrate and the second substrate, wherein the interconnect element has a width, and no joint surface is present in the interconnect element in a range of 50% or more of the width.

### CROSS REFERENCE TO P MATED APPLICATION

This application claims the benefits of the Taiwan Patent Application Serial Number 110129246, filed on Aug. 9, 2021, the subject matter of which is incorporated herein by reference.

### BACKGROUND

### 1. Field

The present disclosure relates to an electrical connecting structure and a method for manufacturing the same. More specifically, the present disclosure relates to an electrical connecting structure having an interconnect element with high strength and a method for manufacturing the same.

### 2. Description of Related Art

With the vigorous development of the electronics industry, there is an increasing demand for electronic products with small size, light weight, multi-function and high performance. In the current development of integrated circuits, in order to install multiple active components and passive components on the same device, semiconductor packaging technology is now used to achieve the purpose of accommodating a larger number of circuits and electronic components in a limited unit area.

In the stacking of package substrates or circuit boards, copper films can be used for stacking; however, the film is not the bump structure and cannot meet the requirement of the interconnect element in the package industry. If the copper bumps using the conventional material are used for stacking, the formed interconnect element is a polycrystalline interconnect element because the lattice direction of the conventional material is not uniform. However, the polycrystalline interconnect element has a high proportion of the area of the grain boundaries, and it is easy to cause electron scattering, resulting in the increase of the resistance. In addition, the mechanical strength of the joint is weak. If a more expensive manufacturing process (such as sputtering) or a relatively expensive material (such as silver) is used, although an interconnect element with high strength and high electrical conductivity can be obtained, its cost is relatively high and it is difficult to apply to industrial manufacturing.

Therefore, it is desirable to develop an electrical connecting structure and a method for manufacturing the same, which can produce an electrical connecting structure with an interconnect element having high strength at a lower manufacturing cost.

### SUMMARY

The present disclosure provides an electrical connecting structure having an interconnect element with high strength and a method for manufacturing the same.

In the present disclosure, the method for manufacturing the electrical connecting structure comprises the following steps: providing a first substrate and a second substrate, wherein a first nano-twinned copper bump is disposed on the first substrate, a second nano-twinned copper bump is disposed on the second substrate, and 50% or more in volume of the first nano-twinned copper bump and 50% or more in volume of the second nano-twinned copper bump respectively comprise plural twinned grains; and bonding the first nano-twinned copper bump and the second nano-twinned copper bump at a temperature ranging from 150° C. to 400° C. to form an interconnect element, wherein the interconnect element has a width, and no joint surface is present in the interconnect element in a range of 50% or more of the width.

By using the aforesaid method of the present disclosure, an electrical connecting structure of the present disclosure can be obtained, which comprises: a first substrate; a second substrate; and an interconnect element disposed between the first substrate and the second substrate, wherein the interconnect element has a width, and no joint surface is present in the interconnect element in a range of 50% or more of the width.

In the present disclosure, by bonding the nano-twinned copper bumps disposed on two substrates at a specific temperature range (150° C. to 400° C.), not only the purpose of bonding the two bumps can be achieved, but also at least a part of the joint surface (also called as the joint interface or the bonding interface) of the interconnect element can be eliminated to obtain an interconnect element with a quasi-single crystal structure. The bonding strength of the interconnect element can be effectively improved as the joint surface of the interconnect element is reduced. Meanwhile, since the interconnect element obtained in the present disclosure has the quasi-single crystal structure and almost no grain boundaries are found, the resistance of the interconnect element can be effectively reduced to further improve the conductivity of the interconnect element. The interconnect element provided by the present disclosure has high bonding strength and low resistance. Therefore, the interconnect element of the present disclosure can be applied to various electronic products, and is further suitable for the wafer level package of high-end electronic products.

In the electrical connecting structure of the present disclosure, no joint surface is present in the interconnect element in a range of 50% or more of the width of the interconnect element. Herein, the joint surface present in the interconnect element can be measured by a cross section of the interconnect element.

In the electrical connecting structure of the present disclosure, in a cross section of the interconnect element, no joint surface is present in a range of 50% or more of the width of the interconnect element, and in particular, no joint surface is present in a continuous range of 50% or more of the width of the interconnect element. In one embodiment of the present disclosure, no joint surface is present in a continuous range of 50% to 100%, 50% to 99%, 60% to 99%, 70% to 99%, 75% to 99%, 80% to 99%, 80% to 95%, 80% to 90% or 85% to 90% of the width of the interconnect element.

In the electrical connecting structure of the present disclosure, the width of the interconnect element can be adjusted according to the need. In one embodiment of the present disclosure, the width of the interconnect element may range from, for example 50 nm to 50 μm 100 nm to 50 μm, 500 nm to 50 μm, 1 μm to 50 μm, 5 μm to 50 μm, 10 μm to 50 μm, 15 μm to 50 μm, 20 μm to 50 μm, 25 μm to 50 μm, 30 μm to 50 μm, 35 μm to 50 μm or 40 μm to 50 μm. Herein, the width of the interconnect element refers to the width of the interconnect element measured at a direction perpendicular to the normal direction of the first substrate or the second substrate.

In the electrical connecting structure of the present disclosure, the thickness of the interconnect element may also be adjusted according to the need. In one embodiment of the present disclosure, the thickness of the interconnect element may range from, for example, 50 nm to 50 μm, 100 nm to 50 μm, 500 nm to 50 μm, 1 μm to 50 μm, 1 μm to 40 μm, 1 μm to 30 μm, 1 μm to 25 μm, 1 μm to 20 μm, 5 μm to 20 μm or 5 μm to 15 μm. Herein, the thickness of the interconnect element refers to the thickness of the interconnect element measured at the normal direction of the first substrate or the second substrate.

In the method of the present disclosure, in the step of bonding the first nano-twinned copper bump and the second nano-twinned copper bump to form the interconnect element, at least a part of the plural twinned grains in the first nano-twinned copper bump and at least a part of the plural twinned grains in the second nano twinned copper bump may be recrystallized to form the interconnect element comprising a monocrystalline grain (also called as a single crystal grain), and the monocrystalline grain may occupy 50% or more of a volume of the interconnect element. By the recrystallization process, the obtained interconnect element may comprise a monocrystalline grain, and the monocrystalline grain may occupy 50% or more of a volume of the interconnect element. Thus, in the electrical connecting structure of the present disclosure, most of the nano-twinned grains are recrystallized into a monocrystalline grain and no longer have the nano-twinned structure. Hence, the formed interconnect element of the electrical connecting structure can be regarded as bonding by a first copper bump disposed on the first substrate and a second copper bump disposed on the second substrate.

In the electrical connecting structure of the present disclosure, the monocrystalline grain may occupy, for example, 50% to 100%, 50% to 99%, 60% to 99%, 70% to 99%, 75% to 99%, 80% to 99%, 80% to 95%, 80% to 90% or 85% to 90% of the volume of the interconnect element.

In the method of the present disclosure, the bonding step may be performed at the temperature ranging from 150° C. to 400° C., for example, 150° C. to 350° C., 150° C. to 300° C., 175° C. to 300° C., 175° C. to 275° C., 200° C. to 275° C., 200° C. to 250° C. or 225° C. to 250° C. If the bonding temperature is too low, the twinned grains in the first nano-twinned copper bump and the second nano twinned copper bump cannot be recrystallized and cannot form the interconnect element comprising the monocrystalline grain.

In the method of the present disclosure, the bonding step may be performed at the pressure ranging from 200 Newton to 500 Newton. In one embodiment of the present disclosure, the bonding step may be performed at the pressure ranging from, for example, 200 Newton to 400 Newton or 250 Newton to 350 Newton.

In the method of the present disclosure, the bonding time may be adjusted according to the size of the first nano-twinned copper bump and the second nano-twinned copper bump. For example, the bonding time may be ranged from 1 minute to 4 hours. In one embodiment of the present disclosure, the bonding time may range from 1 hour to 3 hours.

In the method of the present disclosure, the first and second nano-twinned copper bumps may respectively comprise a nano-twinned copper layer and a transition layer disposed between the nano-twinned copper layer and the first/second substrate. Herein, the thickness of the transition layer may range from 0.3 μm to 1 μm, for example, 0.3 μm to 0.8 μm, 0.3 μm to 0.7 μm, 0.3 μm to 0.6 μm, 0.35 μm to 0.6 μm, 0.35 μm to 0.55 μm, 0.4 μm to 0.55 μm or 0.4 μm to 0.5 μm. If the thickness of the transition layer is too thin, the nano-twinned copper grains cannot be recrystallized and cannot grow across the bonding interface, so the electrical connecting structure with the interconnect element having eliminated joint surface cannot be obtained. If the thickness of the transition layer is too thick, even though the nano-twinned copper grains can be recrystallized and grow into large crystal grains, most of the growth crystal grains cannot grow across the bonding interface, and the electrical connecting structure with the interconnect element having eliminated joint surface still cannot be obtained. Herein, the transition layer refers to the region that the crystal grains do not have a preferred direction.

In the electrical connecting structure and the method of the present disclosure, a first/second insulating layer is disposed on the first/second substrate, the first/second insulating layer comprises a first/second recess, and the first/second nano-twinned copper bump is disposed in the first/second recess; wherein the first/second recess has a first/second side wall, and an angle included between the first/second side wall and a surface of the first/second substrate may be in a range from 70 degrees to 90 degrees.

In the method of the present disclosure, when the aforesaid angle is included between the first/second side wall of the first/second insulating layer on the first/second substrate and the surface of the first/second substrate, the first/second side wall of the first/second insulating layer may be perpendicular or nearly perpendicular to the surface of the first/second substrate. When the first/second nano-twinned copper bump is prepared by an electrodeposition process, the plural twinned grains in the nano-twinned copper layer of the first/second nano-twinned copper bump are connected with each other, and each twinned grains may be formed by staking plural twins along a [111] crystal axis to obtain columnar nano-twinned grains. In addition, since the first/second side wall of the first/second insulating layer may be perpendicular or nearly perpendicular to the surface of the first/second substrate, an angle included between the [111] crystal axes of two adjacent twinned grains of the plural twinned grains may be in a range from 0 degree to 20 degrees in the obtained first/second nano-twinned copper bump. Thus, at least 50% of an area of a surface of the first/second nano-twinned copper bump may expose a (111) surface of the plural twinned grains, and the surface of the first/second nano-twinned copper bump has a (111) preferred direction.

In the present disclosure, at least 50% of an area of a surface of the first/second nano-twinned copper bump may expose a (111) surface of the plural twinned grains, and the surface of the first/second nano-twinned copper bump has a (111) preferred direction. In one embodiment of the present disclosure, the exposed (111) surface of the nano-twins on the surface of the first/second nano-twinned copper bump may be, for example, 50% to 99%, 55% to 99%, 60% to 99%, 65% to 99%, 70% to 99%, 75% to 99%, 75% to 95% or 75% to 90% of the total area of the surface of the first/second nano-twinned copper bump, but the present disclosure is not limited thereto.

In the present disclosure, the angle included between the [111] crystal axes of two adjacent twinned grains of the plural twinned grains may be in a range from 0 degree to 20 degrees. In other words, the twinned grains in the nano-twinned copper layer of the first/second nano-twinned copper bump may be columnar grains perpendicular or nearly perpendicular to the surface of the first/second substrate. When the twinned grains in the nano-twinned copper layer of the first/second nano-twinned copper bump are perpendicular or nearly perpendicular columnar grains, the interconnect element with the quasi-single crystal structure can be obtained by bonding at the suitable temperature.

In the present disclosure, the first substrate and the second substrate may respectively be a semiconductor chip, a package substrate or a circuit board, and more preferably is a semiconductor wafers. Thus, the present disclosure can be applied to various package techniques derived from IBM C4 techniques, such as flip chip, wafer bonding, wafer level chip scale packaging (WLCSP), etc., and in particular, high-frequency and high-power component. In particular, the present disclosure can also be applied to three-dimensional integrated circuits (3D-ICs) that require high mechanical properties and product reliability. For example, when the first substrate and the second substrate are semiconductor wafers, the 3D-IC can be obtained after the bonding step. In addition, the bonding step may be performed by using the 3D-IC as the first substrate and using the packaging substrate as the second substrate. Herein, the aforementioned examples are used only as an example, and the present disclosure is not limited thereto.

In the present disclosure, the diameters of the plural twinned grains may be respectively ranged from 0.1 μm to 50 μm. In one embodiment of the present disclosure, the diameters of the twinned grains may be ranged from, for example, 0.1 μm to 45 μm, 0.1 μm to 40 μm, 0.1 μm to 35 μm, 0.5 μm to 35 μm, 0.5 μm to 30 μm, 0.5 μm to 25 μm, 0.5 μm to 20 μm, 0.5 μm to 15 μm, 0.5 μm to 10 μm, 0.5 μm to 5 μm, 0.5 μm to 3 μm or 0.5 μm to 2 μm; but the present disclosure is not limited thereto. In the present disclosure, the diameters of the twinned grains may be the lengths measured in a direction substantially perpendicular to the twin direction of the twinned grains. More specifically, the diameters of the twinned grains may be the lengths (for example, the maximum length) measured in a direction substantially perpendicular to the lamination direction of the twins or the twin boundaries (i.e., the extension direction of the twin boundary).

In the present disclosure, the thicknesses of the plural twinned grains may be respectively ranged from 0.1 μm to 500 μm. In one embodiment of the present disclosure, the thickness of the twinned grains may be ranged from, for example, 0.1 μm to 500 μm, 0.1 μm to 400 μm, 0.1 μm to 300 μm, 0.1 μm to 200 μm, 0.1 μm to 100 μm, 0.1 μm to 80 μm, 0.1 μm to 50 μm, 1 μm to 50 μm, 2 μm to 50 μm, 3 μm to 50 μm, 4 μm to 50 μm, 5 μm to 50 μm, 5 μm to 40 μm, 5 μm to 35 μm, 5 μm to 30 μm or 5 μm to 25 μm. In the present disclosure, the thicknesses of the twinned grains may be the thicknesses of the twinned grains measured at the twin direction of the twinned grains. More specifically, the thicknesses of the twinned grains may be the thicknesses (for example, maximum thicknesses) of the twinned grains measured at the lamination direction of the twins or the twin boundaries.

In the present disclosure, “the twin direction of the twinned grain” refers to the lamination direction of the twins or the twin boundaries in the twinned grains. Herein, the twin boundaries of the twinned grains may be substantially perpendicular to the lamination direction of the twins or the twin boundaries. In the present disclosure, the twinned grains are formed by staking plural twins along the [111] crystal axes.

In the present disclosure, the width and thickness of the first and second nano-twinned copper bumps can be adjusted according to the width and thickness of the desired interconnect element to obtain the interconnect element having desired width and thickness.

In the present disclosure, the method for measuring the aforesaid features of the interconnect element and the aforesaid features of the nano-twinned copper bump is not particularly limited, and may be scanning electron microscope (SEM), transmission electron microscope (TEM), focus ion beam (FIB), electron backscatter diffraction (EBSD) or other suitable measurement manners.

In the present disclosure, the method for preparing the first and second nano-twinned copper bumps is not particularly limited, and the first and second nano-twinned copper bumps may be prepared by, for example, electrodeposition. In one embodiment of the present disclosure, the first and second nano-twinned copper bumps may be prepared by the following steps: providing an electrodeposition device, comprising an anode, a cathode, a plating solution and a power supply, wherein the power supply is respectively connected to the cathode and the anode, and the cathode and the anode are immersed into the plating solution; and performing an electrodeposition process with the electrodeposition device to grow the nano-twinned copper layer on a surface of the cathode.

In the present disclosure, the cathode may be the aforesaid first/second substrate disposed with the first/second insulating layer. Herein, the first/second substrate may be a substrate with a metal layer formed thereon or a metal substrate. The first/second substrate may be a silicon substrate, a glass substrate, a quartz substrate, a metal substrate, a plastic substrate, a print circuit board, a III-IV group substrate or a lamination substrate thereof. Furthermore, the first/second substrate may have a single-layer or multi-layer structure.

In the present disclosure, the plating solution may comprise a copper salt, a hydrochloric acid, and an acid other than hydrochloric acid. Examples of the copper salt comprised in the plating solution may comprise, but are not limited to, copper sulfate, methyl sulfonic copper or a combination thereof. Examples of the acid comprised in the plating solution may comprise, but are not limited to, sulfuric acid, methane sulfonic acid or a combination thereof. In addition, the plating solution may further comprise an additive, such as gelatin, surfactants, lattice modification agents or a combination thereof.

In the present disclosure, the electrodeposition process may be performed with direct current electrodeposition, high-speed pulse electrodeposition, or direct current electrodeposition and high-speed pulse electrodeposition interchangeably to form the nano-twinned copper layer. In one embodiment of the present disclosure, the nano-twinned copper layer may be prepared by direct current electrodeposition. The current density used in the direct current electrodeposition may be ranged from, for example, 0.5 ASD to 30 ASD, 1 ASD to 30 ASD, 2 ASD to 30 ASD 2 ASD to 25 ASD, 3 ASD to 25 ASD, 3 ASD to 20 ASD or 4 ASD to 20 ASD; but the present disclosure is not limited thereto.

Other novel features of the disclosure will become more apparent from the following detailed description when taken in conjunction with the accompanying drawings.

### BRIEF DESCRIPTION OF THE DRAWINGS

FIG. 1A and FIG. 1B are cross-sectional views showing the method for manufacturing an electrical connecting structure of the present disclosure.

FIG. 2 is an EBSD photo of a nano-twinned copper bump prepared in Embodiment 1 of the present disclosure.

FIG. 3 is a FIB photo of a nano-twinned copper bump prepared in Embodiment 1 of the present disclosure.

FIG. 4 is an EBSD photo of an electrical connecting structure prepared in Embodiment 1 of the present disclosure.

FIG. 5 is a FIB photo of an electrical connecting structure prepared in Embodiment 1 of the present disclosure.

FIG. 6 is an EBSD photo of an electrical connecting structure prepared in Comparative embodiment 1 of the present disclosure.

FIG. 7 is a FIB photo of an electrical connecting structure prepared in Comparative embodiment 1 of the present disclosure.

FIG. 8 is a FIB photo of an electrical connecting structure prepared in Embodiment 4 of the present disclosure.

FIG. 9 are FIB photos of nano-twinned copper bumps prepared in Embodiment 5 to Embodiment 8 of the present disclosure, wherein (a) is the FIB photo of the nano-twinned copper bump prepared in Embodiment 5, (b) is the FIB photo of the nano-twinned copper bump prepared in Embodiment 6, (c) is the FIB photo of the nano-twinned copper bump prepared in Embodiment 7, and (d) is the FIB photo of the nano-twinned copper bump prepared in Embodiment 8.

FIG. 10 are FIB photos of electrical connecting structures prepared in Embodiment 5 to Embodiment 8 of the present disclosure, wherein (a) is the FIB photo of the electrical connecting structure prepared in Embodiment 5, (b) is the FIB photo of the electrical connecting structure prepared in Embodiment 6, (c) is the FIB photo of the electrical connecting structure prepared in Embodiment 7, and (d) is the FIB photo of the electrical connecting structure prepared in Embodiment 8.

FIG. 11A and FIG. 11B are respectively FIB photos of nano-twinned copper bumps prepared in Embodiment 9 and Embodiment 10 of the present disclosure.

FIG. 12A and FIG. 12B are respectively FIB photos of electrical connecting structures prepared in Embodiment 9 and Embodiment 10 of the present disclosure.

### DETAILED DESCRIPTION OF EMBODIMENT

Different embodiments of the present disclosure are provided in the following description. These embodiments are meant to explain the technical content of the present disclosure, but not meant to limit the scope of the present disclosure. A feature described in an embodiment may be applied to other embodiments by suitable modification, substitution, combination, or separation.

It should be noted that, in the present specification, when a component is described to have an element, it means that the component may have one or more of the elements, and it does not mean that the component has only one of the element, except otherwise specified.

In the present specification, except otherwise specified, the feature A “or” or “and/or” the feature B means the existence of the feature A, the existence of the feature B, or the existence of both the features A and B. The feature A “and” the feature B means the existence of both the features A and B. The term “comprise(s)”, “comprising”, “include(s)”, “including”, “have”, “has” and “having” means “comprise(s)/comprising but is/are/being not limited to”.

Moreover, in the present specification, when an element is described to be arranged “on” another element, it does not essentially means that the elements contact the other element, except otherwise specified. Such interpretation is applied to other cases similar to the case of “on”.

Moreover, in the present specification, a value may be interpreted to cover a range within ±10% of the value, and in particular, a range within ±5% of the value, except otherwise specified; a range may be interpreted to be composed of a plurality of subranges defined by a smaller endpoint, a smaller quartile, a median, a greater quartile, and a greater endpoint, except otherwise specified.

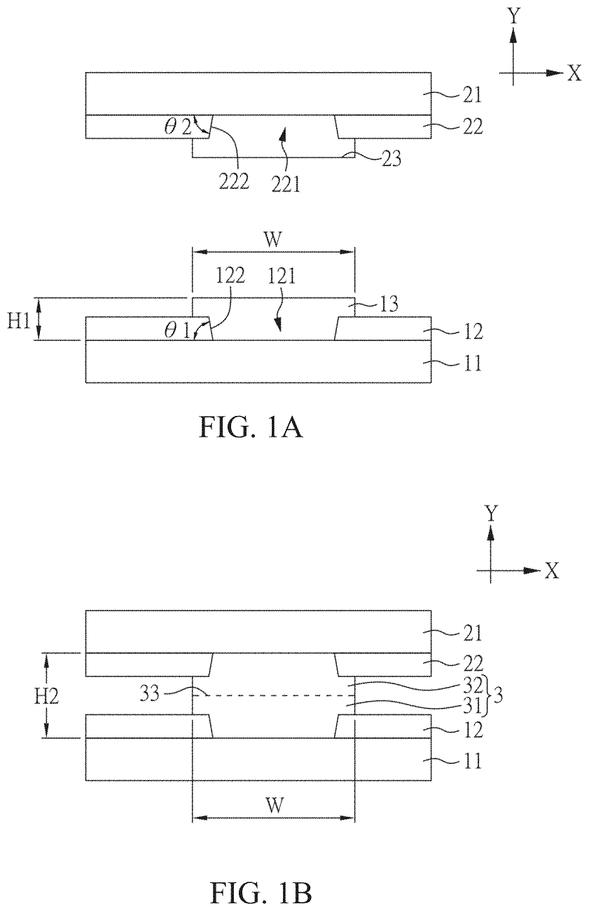

FIG. 1A and FIG. 1B are cross-sectional views showing the method for manufacturing an electrical connecting structure of the present disclosure. As shown in FIG. 1A, a first substrate 11 and a second substrate 21 are provided, wherein, a first nano-twinned copper bump 13 is disposed on the first substrate 11, and a second nano-twinned copper bump 23 is disposed on the second substrate 21. In addition, 50% or more in volume of the first nano-twinned copper bump 13 and 50% or more in volume of the second nano-twinned copper bump 23 respectively comprise plural twinned grains.

More specifically, a first insulating layer 12 is disposed on the first substrate 11, the first insulating layer 12 comprises a first recess 121, and the first nano-twinned copper bump 13 is disposed in the first recess 121; wherein the first recess 121 has a first side wall 122, and an angle θ1 included between the first side wall 122 and a surface of the first substrate 11 is in a range from 70 degrees to 90 degrees. In addition, a second insulating layer 22 is disposed on the second substrate 21, the second insulating layer 22 comprises a second recess 221, and the second nano-twinned copper bump 23 is disposed in the second recess 221; wherein the second recess 221 has a second side wall 222, and an angle θ2 included between the second side wall 222 and a surface of the second substrate 21 is in a range from 70 degrees to 90 degrees.

Next, the first nano-twinned copper bump 13 and the second nano-twinned copper bump 23 are bonded at a temperature ranging from 1150° C. to 400° C., to form an interconnect element 3, wherein the interconnect element 3 has a width W, and no joint surface 33 is present in the interconnect element 3 in a range of 50% or more of the width W.

More specifically, when the first nano-twinned copper bump 13 and the second nano-twinned copper bump 23 are bonded to form the interconnect element 3, the twinned grains in the first nano-twinned copper bump 13 and the second nano-twinned copper bump 23 are recrystallized. Thus, in the obtained electrical connecting structure, the first nano-twinned copper bump 13 is transferred into the first copper bump 31 in which the twinned boundaries are almost eliminated, and the second nano-twinned copper bump 23 is also transferred into the second copper bump 32 in which the twinned boundaries are almost eliminated. Therefore, the obtained interconnect element 3 can be considered as being formed by bonding the first copper bump 31 on the first substrate 11 and the second copper bump 32 on the second substrate 21.

After the aforesaid process, the electrical connecting structure of the present disclosure can be obtained, which comprises: a first substrate 11; a second substrate 21; and an interconnect element 3 disposed between the first substrate 11 and the second substrate 21, wherein the interconnect element 3 has a width W and no joint surface 33 is present in the interconnect element 3 in a range of 50% or more of the width W. In particular, in a cross section of the interconnect element 3, no joint surface 33 is present in a continuous range of 50% or more of the width W. In addition, the interconnect element 3 comprises a monocrystalline grain, and the monocrystalline grain occupies 50% or more of a volume of the interconnect element 3.

### Embodiment 1

In the present embodiment, 8-inch silicon wafers coated with 100 nm Ti—W/200 nm Cu were used as the cathodes for electrodeposition, wherein the silicon wafers can be regarded as the first substrate 11 and the second substrate 21 shown in FIG. 1A and FIG. 1B. In addition, insulating layers were formed on the silicon wafers, the insulating layers have openings, and these openings define the regions for the sequentially formed nano-twinned copper bumps. Herein, the insulating layers can be regarded as the first insulating layer 12 and the second insulating layer 22 shown in FIG. 1A and FIG. 1B, and the openings of the insulating layers can be regarded as the first recess 121 and the second recess 221. The material of the insulating layers may be PBO, PI, SiO₂, SiCN, SiN, underfill, silicon on glass (SOG) or a combination thereof. In the present embodiment, the material of the insulating layers is SiO₂. The thickness of the insulating layer may be ranged from 50 nm to 50 μm, and the insulating layers can be firmed by plasma-enhanced chemical vapor deposition (PECVD) or any other coating process known in the art.

Next, the electrodeposition of the nano-twinned copper layer was performed. The plating solution used herein was formulated by CuSO₄ powders, H₂SO₄, HCl and an additive (108C, provided by Chemleader Corporation). 196.61 g of CuSO₄.5H₂O was added, followed by adding 100 g of H₂SO₄ (96%), 0.1 ml of HCl and 35 ml of additive. Then, de-ionized water was added until the volume of the total solution was 1 L. The plating solution was stirred with a stir bar until the solution was mixed well. After mixing, the plating solution was placed into an electroplating tank, and the stir bar was stirred at 1200 rpm/min to maintain the flow of the plating solution. The electrodeposition was performed at room temperature and atmospheric pressure. The power supply (Keithley 2400) was controlled by the computer. For example, when the direct current electrodeposition was performed with a current density of 10 ASD (A/dm²) for 10 minutes, the nano-twinned copper pillar with columnar grains can be obtained, wherein the thickness of the nano-twinned copper pillar (i.e. the thickness H1 shown in FIG. 1A) was about 6 to 8 μm, and the width (i.e. the width W shown in FIG. 1A) was about 45 μm. The obtained nano-twinned copper pillar can be used as the first nano-twinned copper bump 13 and the second nano-twinned copper bump 23 shown in FIG. 1A and FIG. 1B.

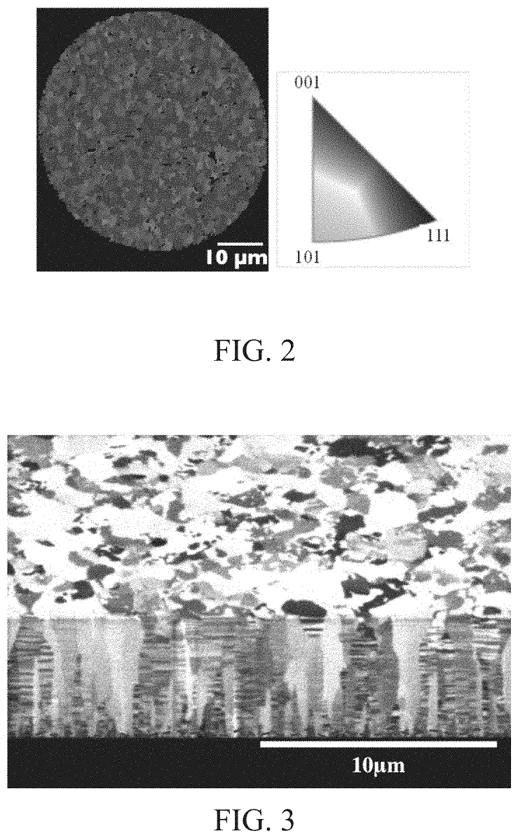

FIG. 2 and FIG. 3 are respectively an EBSD photo and a FIB photo of the nano--twinned copper bump prepared in the present embodiment. In the nano-twinned copper pillar obtained in the present embodiment, almost all the volume (97% or more of the volume) of the nano-twinned copper pillar are formed by columnar twinned grains connecting with each other, the diameter of the columnar twinned grain is about 0.87 μm, and the thickness of the transition layer is about 0.3 μm. In addition, the twinned grains are formed by staking nano-twins along a [111] crystal axis, an angle included between the [111] crystal axes of two adjacent nano-twinned grains is about 0 degree, and the twin boundaries of the nano-twins are substantially parallel to the surface of the substrate (i.e. the stacking direction of the nano-twins is substantially parallel to the thickness direction (Y) of the nano-twinned copper pillar). Therefore, almost all the surface of the nano-twinned copper pillar (97% or more of the area) exposes the (111) surface of the nano-twins, indicating that the nano-twinned copper pillar of the present embodiment has a (111) preferred direction. Furthermore, the angle included between the twin direction of 95% or more of the twinned grains and the thickness (Y) direction of the nano-twinned copper pillar is about 0 degree, and the angle included between the twin direction of 95% or more of the twinned grains and the surface of the substrate is about 90 degrees. This indicates that the twin boundaries of the twin grains are substantially parallel to the surface of the substrate. In addition, 95% or more of the twinned grains of the nano-twinned copper pillar have thicknesses ranging from 1 μm to 20 μm.

Next, the backside of the silicon wafer was polished until the thickness of the silicon wafer was about 500 μm to facilitate the thermal compression bonding. An ultraviolet microscope was used to facilitate the alignment of the wafers because the UV light can penetrate through the wafers. Then, chemical-mechanical planarization (CMP) was used to reduce the roughness of the surface of the nano-twinned copper pillar into 2˜5 nm. The silicon wafer after polishing was cut into a top die (6 mm×6 mm) and a bottom die (15 mm×15 mm). The dies were cleaned with hot citric acid to remove the oxides on the surface of the dies. In an environment with a vacuum pressure of 10⁻³ torr, the top die and the bottom die were bonded at 250° C., under 300 Newton for 2 hours to obtain the electrical connecting structure of the present embodiment. In the obtained electrical connecting structure, the thickness of the interconnect element (i.e. the thickness H2 shown in FIG. 13) is about 12˜16 μm, and the width (i.e. the width W shown in FIG. 1B) is about 45 μm.

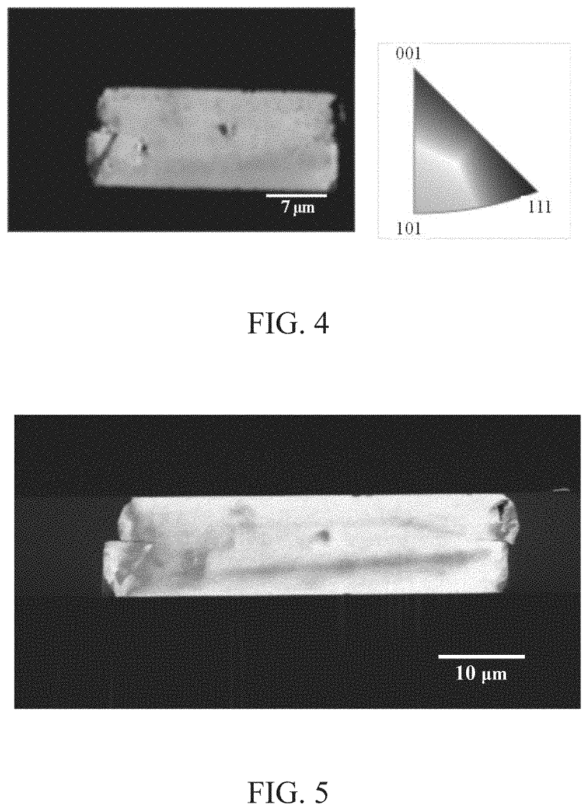

The structure of the interconnect element obtained by thermal compression bonding was analyzed by EBSD and FIB. FIG. 4 and FIG. 5 are respectively an EBSD photo and a FIB photo of the electrical connecting structure obtained in the present disclosure. As shown in FIG. 4, after thermal compression bonding at 250° C., the original nano-twinned copper pillar was recrystallized and grew into a larger grain, and an interconnect element with quasi-single crystal structure can be obtained, in which 80% of the bonding interface was eliminated. Similarly, as shown in FIG. 5, almost no crystal boundary was observed in the interconnect element, and 80% of the bonding interface was eliminated.

The above results indicate that the twinned grains in the nano-twinned copper pillar can be recrystallized and grow into larger grain by thermal compression process at a suitable temperature, and no crystal boundary was observed in the obtained interconnect element. In addition, the larger grain can grow across the bonding interface, so 80% or more of the bonding interface between the copper pillars can be eliminated. Therefore, no joint surface is present in the interconnect element in a continuous range of 80% or more of the width of the interconnect element, and the interconnect element with quasi-single crystal structure can be obtained.

### Comparative Embodiment 1

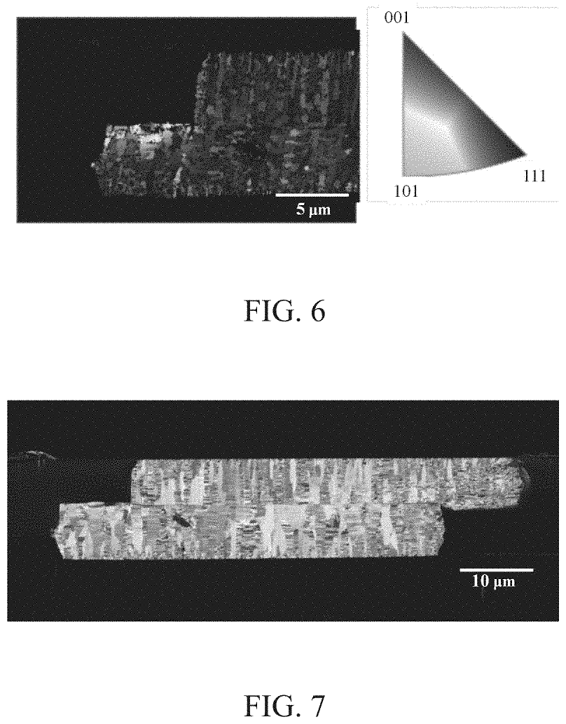

The method for preparing the electrical connecting structure of the present comparative embodiment is similar to that illustrated in Embodiment 1, except that the temperature of the thermal compression bonding was 150° C. in the present embodiment. FIG. 6 and FIG. 7 are respectively an EBSD photo and a FIB photo of the electrical connecting structure prepared in the present comparative embodiment.

As shown in FIG. 6 and FIG. 7, when the nano-twinned copper pillars were bonded by thermal compression bonding at 150° C., although the nano-twinned copper pillars can be successfully bonded, the twin grains in the nano-twinned copper pillars still maintain in high density and the bonding interface between the nano-twinned copper pillars still exists. It is because the thickness of the transition layer is thin, but the twinned grains are not small enough to grow large grain at this temperature.

In addition, the tensile strengths of the electrical connecting structures obtained by bonding the same nano-twinned copper bumps at different temperatures, pressures and times were compared, and the results are shown in the following Table 1.

TABLE 1

| | Bonding | Bonding | | Tensile |
|---|---|---|---|---|
| | temperature | pressure | Bonding | strength |
| | (° C.) | (MPa) | time | (MPa) |
| Embodiment | 250 | 41.5 | 2 hours | 32.9 |
| 1 | | | | |
| Embodiment | 200 | 41.5 | 2 hours | 19.89 |
| 2 | | | | |
| Embodiment | 250 | 41.5 | 60 seconds | 9.78 |
| 3 | | | | |
| Comparative | 150 | 41.5 | 2 hours | 0.82 |
| embodiment | | | | |
| 1 | | | | |

The results shown in Table 1 indicate that the electrical connecting structures obtained in Embodiment 1 to Embodiment 3 have larger tensile strength than that obtained in Comparative embodiment 1. It should be noted that, the tensile strength of the electrical connecting structure obtained in Embodiment 1 should be greater than 32.9 MPa. This is because the test specimen was not broken at the bonding interface, but the fracture was occurred on the silicon wafer.

### Embodiment 4

The method for preparing the electrical connecting structure of the present embodiment is similar to that illustrated in Embodiment 1, except for the following differences.

First, a first insulating layer was deposited on the silicon wafer by plasma-enhanced chemical vapor deposition (PECVD), and the material of the first insulating layer may be, for example, SiO₂, SiCN, SiN or a combination thereof. In the present embodiment, the material of the first insulating layer was SiO₂. Next, a second insulating layer was formed, and the material of the second insulating layer may be positive resin or negative resin. The first insulating layer was patterned by the etching process to define a region having a width ranging from 50 nm to 100 μm. Next, the second insulating layer was removed. The same process for electrodeposition illustrated in Embodiment 1 was performed to obtain the nano-twinned copper pillar of the present embodiment, which has similar structure of the nano-twinned copper pillar obtained in Embodiment 1. In addition, in the present embodiment, except for the joint surface, the peripheral surface of the nano-twinned copper pillar is surrounded by the first insulating layer.

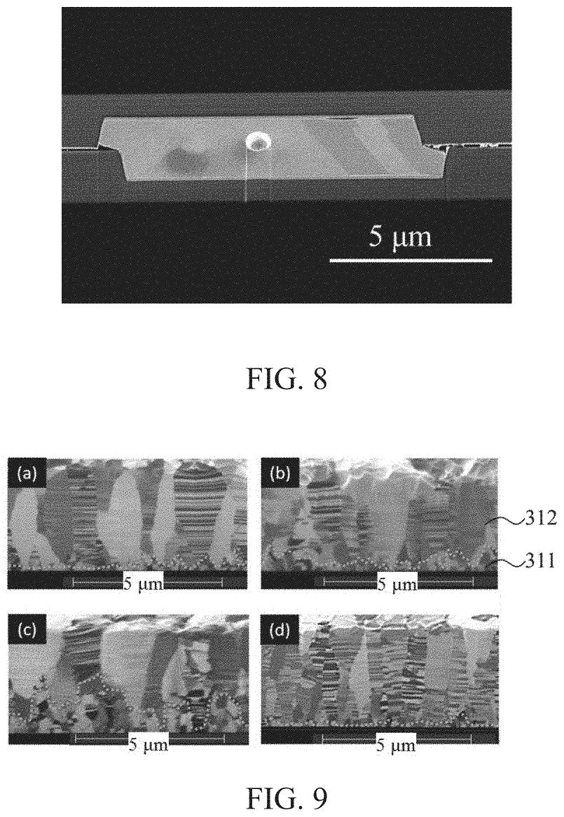

After the surface of the nano-twinned copper pillar was planarized with CMP, the same thermal compression bonding of Embodiment 1 was performed herein to obtain the electrical connecting structure of the present embodiment. FIG. 8 is a FIB photo of the electrical connecting structure prepared in the present embodiment, which indicates that 50% or more of the bonding interface in the interconnect element was eliminated.

### Embodiment 5 to Embodiment 10

The method for preparing the nano-twinned copper bump of the present embodiments is similar to that illustrated in Embodiment 1. Herein, the same current density was used, but different temperatures for the electrodeposition (from 0° C. to 100° C.) were used to control the grain size and the thickness of the transition layer. In addition, by using the similar thermal compression bonding illustrated in Embodiment 1, the electrical connecting structures of the present embodiments can be obtained. In Embodiments 5 to 8, the bonding temperature was 250° C. and the bonding time was 2 hours. In Embodiment 9, the bonding temperature was 175° C. and the bonding time was 90 minutes. In Embodiment 10, the bonding temperature was 150° C. and the bonding time was 90 minutes.

FIG. 9 are FIB photos of nano-twinned copper bumps prepared in Embodiment 5 to Embodiment 8 of the present disclosure, wherein (a) to (d) are respectively the FIB photos of the nano-twinned copper bumps prepared in Embodiment 5 to Embodiment 8. Herein, the nano-twinned copper bump comprises a transition layer 311 (i.e. the region below the dotted line) and a nano-twinned copper layer 312 (i.e. the region above the dotted line). As shown in FIG. 9(a), the average thickness of the transition layer of the nano-twinned copper bump prepared in Embodiment 5 was about 0.23 μm, and the diameter of the columnar nano-twinned grains was about 1.2˜1.5 μm. As shown in FIG. 9(b), the average thickness of the transition layer of the nano-twinned copper bump prepared in Embodiment 6 was about 0.45 μm, and the diameter of the columnar nano-twinned grains was about 1.2˜1.5 μm. As shown in FIG. 9(c), the average thickness of the transition layer of the nano-twinned copper bump prepared in Embodiment 7 was about 1.1 μm, and the diameter of the columnar nano-twinned grains was about 1.2˜1.5 μm. As shown in FIG. 9(d), the average thickness of the transition layer of the nano-twinned copper bump prepared in Embodiment 8 was about 0.33 μm, and the diameter of the columnar nano-twinned grains was about 0.71 μm.

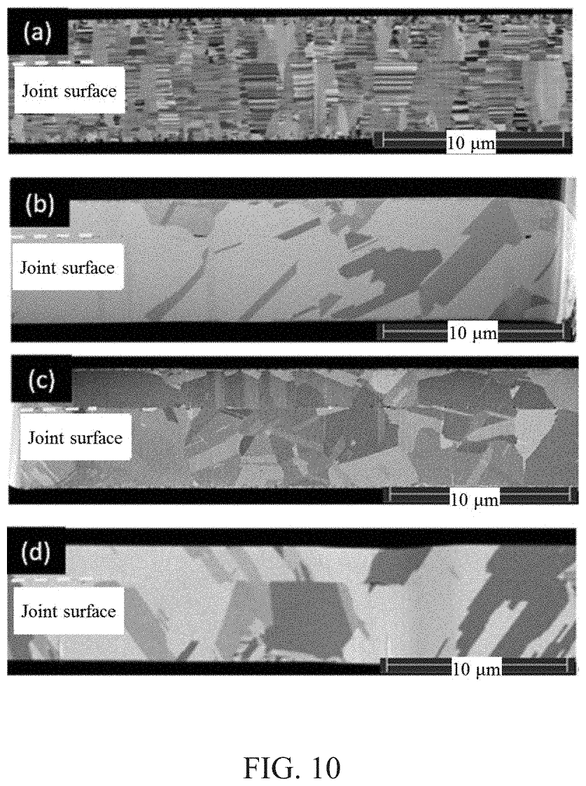

FIG. 10 are FIB photos of electrical connecting structures prepared in Embodiment 5 to Embodiment 8 of the present disclosure, wherein (a) to (d) are respectively the FIB photos of the electrical connecting structure prepared in Embodiment 5 to Embodiment 8.

As shown in FIG. 9(a) and FIG. 10(a), when the transition layer is too thin, most of the grains cannot grow across the joint surface, and the electrical connecting structure that the joint surface is eliminated cannot be obtained. As shown in FIG. 9(b) and FIG. 10(b), when the transition layer has a suitable thickness, all the transition layer is almost eliminated, and most of the grains can be recrystallized and grow across the joint surface. Thus, the electrical connecting structure that the joint surface is eliminated can be obtained, and a large crystal grain can be obtained. However, as shown in FIG. 9(c) and FIG. 10(c), when the transition layer is too thick, even though the grains can be recrystallized, most of the grains cannot grow across the joint surface, and the electrical connecting structure that the joint surface is eliminated cannot be obtained. In addition, as shown in FIG. 9(d) and FIG. 10(d), the transition layer is thin (the thickness of the transition layer shown in FIG. 9(d) is similar to that shown in FIG. 9(a)), and the size of the twinned grains is small. Thus, during the bonding process, the internal system energy increases due to the finer grains and the more grain boundaries, which can cause large grains to grow and grow across the joint surface to obtain the electrical connecting structure that the joint surface is almost eliminated.

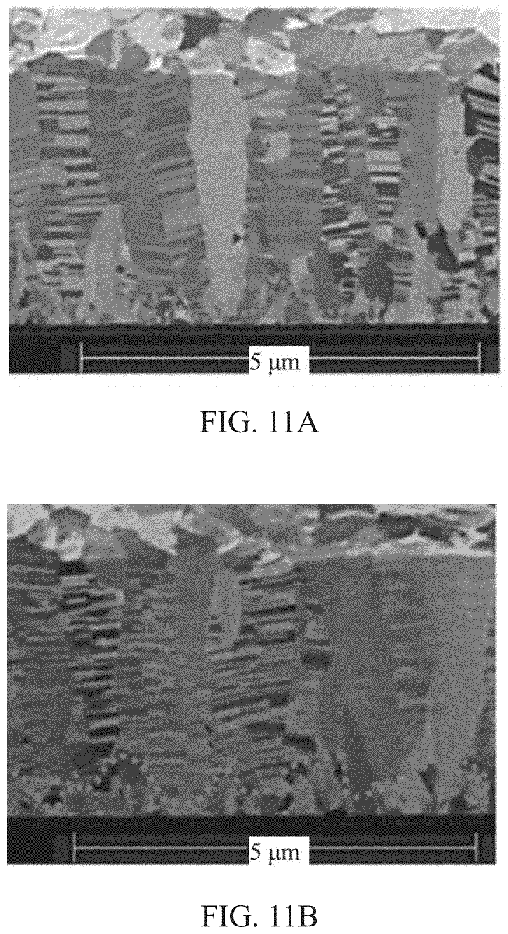

FIG. 11A and FIG. 11B are respectively FIB photos of nano-twinned copper bumps prepared in Embodiment 9 and Embodiment 10 of the present disclosure. Herein, the nano-twinned copper bump of Embodiment 9 has the transition layer with the average thickness of about 0.33 μm, and the diameter of the columnar nano-twinned grains is about 0.74 μm. The nano-twinned copper bump of Embodiment 10 has the transition layer with the average thickness of about 0.45 μm, and the diameter of the columnar nano-twinned grains is about 0.52 μm.

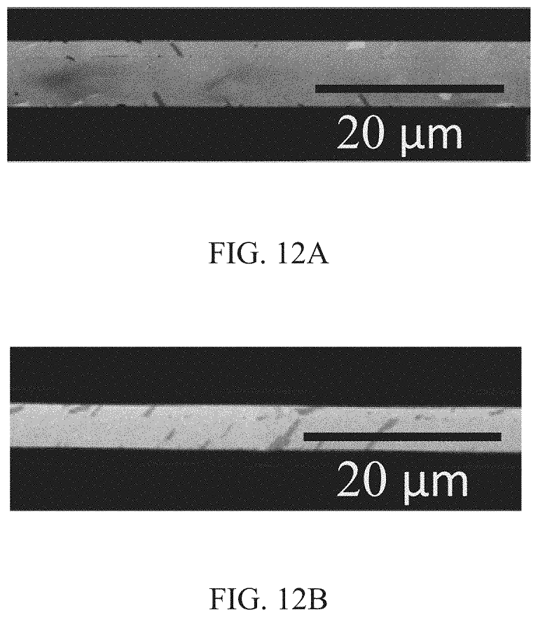

FIG. 12A and FIG. 12B are FIB photos of electrical connecting structures prepared in Embodiment 9 and Embodiment 10 of the present disclosure. As shown in FIG. 12A and FIG. 12B, when the twinned grains has small size, the internal system energy increases during the bonding process due to the finer grains and the more grain boundaries, which can cause large grains to grow and grow across the joint surface to obtain the electrical connecting structure that the joint surface is almost eliminated.

The aforementioned results indicate that when the transition layer is too thin, the nano-twinned copper grains cannot be recrystallized and cannot grow across the joint surface, so the electrical connecting structure that the joint surface is almost eliminated cannot be obtained. When the transition layer is too thick, the twinned copper grains can be recrystallized to grow larger crystal grain, but most of the growth crystal grains cannot grow across the joint surface, so the electrical connecting structure that the joint surface is almost eliminated cannot be obtained. When the transition layer has suitable thickness, if it is desirable to obtain the electrical connecting structure that the joint surface is almost eliminated at low bonding temperature, the thickness of the transition layer has to be thin (but still in the suitable thickness range) and the grain size of the twinned grains has to be small. If the thickness of the transition layer is relatively thin (but still in the suitable thickness range) and the grain size of the twinned grain is relative large, the electrical connecting structure that the joint surface is almost eliminated can be obtained at higher bonding temperature.

In the present disclosure, the nano-twinned copper bumps with (111) preferred direction are bonded at specific temperature (150° C. to 400° C.), the twinned grains in the nano-twinned copper bumps are recrystallized to grow the large grain, and the growth large grain can grow across the joint surface. In addition, by controlling the transition layer in the nano-twinned copper bump having suitable thickness or reducing the size of the twinned grains in the nano-twinned copper bump, the twinned grains in the nano-twinned copper bump can be recrystallized to grow large grain, and the growth large grain can grow across the joint surface. Thus, in the electrical connecting structure provided by the present disclosure, almost all the original grain boundaries of the nano-twinned grains are not observed, and almost all the joint surface of the interconnect element is eliminated. Thus, the electrical connecting structure of the present disclosure has high strength, high electrical conductivity, high thermal conductivity or high electromigration life, and the manufacturing cost of the electrical connecting structure is also low. Therefore, the electrical connecting structure of the present disclosure has potential to be applied to microelectronics 3D-IC package.

Although the present disclosure has been explained in relation to its embodiment, it is to be understood that many other possible modifications and variations can be made without departing from the spirit and scope of the disclosure as hereinafter claimed.

What is claimed is:

1. An electrical connecting structure, comprising:
a first substrate;
a second substrate; and
an interconnect element disposed between the first substrate and the second substrate, wherein the interconnect element has a width, and no joint surface is present in the interconnect element in a range of 50% or more of the width.

2. The electrical connecting structure of claim 1, wherein no joint surface is present in a range of 50% or more of the width in a cross section of the interconnect element.

3. The electrical connecting structure of claim 2, wherein no joint surface is present in a continuous range of 50% or more of the width in the cross section of the interconnect element.

4. The electrical connecting structure of claim 1, wherein the interconnect element comprises a monocrystalline grain, and the monocrystalline grain occupies 50% or more of a volume of the interconnect element.

5. The electrical connecting structure of claim 1, wherein the width of the interconnect element ranges from 50 nm to 50 μm. 6, The electrical connecting structure of claim 1, wherein a thickness of the interconnect element ranges from 50 nm to 50 μm.

7. The electrical connecting structure of claim 1, wherein the interconnect element is obtained by bonding a first copper bump disposed on the first substrate and a second copper bump disposed on the second substrate.

8. The electrical connecting structure of claim 7, wherein a first insulating layer is disposed sin the first substrate, the first insulating layer comprises a first recess, and the first copper bump is disposed in the first recess; wherein the first recess has a first side wall, and an angle included between the first side wall and a surface of the first substrate is in a range from 70 degrees to 90 degrees.

9. The electrical connecting structure of claim 7, wherein a second insulating layer is disposed on the second substrate, the second insulating layer comprises a second recess, and the second copper bump is disposed in the second recess; wherein the second recess has a second side wall, and an angle included between the second side wall and a surface of the second substrate is in a range from 70 degrees to 90 degrees.

10. A method for manufacturing an electrical connecting structure, comprising the following steps:
providing a first substrate and a second substrate, wherein a first nano-twinned copper bump is disposed on the first substrate, a second nano-twinned copper bump is disposed on the second substrate, and 50% or more in volume of the first nano-twinned copper bump and 50% or more in volume of the second nano-twinned copper bump respectively comprise plural twinned grains; and
bonding the first nano-twinned copper bump and the second nano-twinned copper bump at a temperature ranging from 150° C. to 400° C., to form an interconnect element, wherein the interconnect element has a width, and no joint surface is present in the interconnect element in a range of 50% or more of the width.

11. The method of claim 10, wherein no joint surface is present in a range of 50% or more of the width in a cross section of the interconnect element.

12. The method of claim 11, wherein no joint surface is present in a continuous range of 50% or more of the width in the cross section of the interconnect element.

13. The method of claim 10, wherein in the step of bonding the first nano-twinned copper hump and the second nano-twinned copper bump to form the interconnect element, at least a part of the plural twinned grains in the first nano-twinned copper bump and at least a part of the plural twinned grains in the second nano-twinned copper bump are recrystallized to form the interconnect element comprising a monocrystalline grain, and the monocrystalline grain occupies 50% or more of a volume of the interconnect element.

14. The method of claim 10, wherein the width of the interconnect element ranges from 50 nm to 50 μm.

15. The method of claim 10, wherein a thickness of the interconnect element ranges from 50 nm to 50 μm.

16. The method of claim 10, wherein a first insulating layer is disposed on the first substrate, the first insulating layer comprises a first recess, and the first nano-twinned copper bump is disposed in the first recess; wherein the first recess has a first side wall, and an angle included between the first side wall and a surface of the first substrate is in a range from 70 degrees to 90 degrees.

17. The method of claim 10, wherein a second insulating layer is disposed on the second substrate, the second insulating layer comprises a second recess, and the second nano-twinned copper bump is disposed in the second recess; wherein the second recess has a second side wall, and an angle included between the second side wall and a surface of the second substrate is in a range from 70 degrees to 90 degrees.

18. The method of claim 10, wherein at least 50% of an area of a surface of the first nano-twinned copper bump and at least 50% of an area of a surface of the second nano-twinned copper bump respectively expose a (111) surface of the plural twinned grains.

19. The method of claim 10, wherein the plural twinned grains are connected with each other, and each of the plural twinned grains is thrilled by staking plural twins along a [111] crystal axis.

20. The method of claim 19, wherein an angle included between the [111] crystal axes of two adjacent twinned grains of the plural twinned grains is in a range from 0 degree to 20 degrees.
